(19) United States
(12) Patent Application Publication
(10) Pub. No.: US 2026/0231329 A1
(43) Pub. Date: Aug. 6, 2026

(54) METHOD AND APPARATUS FOR MATCHING INDUCTORS THROUGH A SUBSTRATE CARRIER OR CORE

(71) Applicant: Atlas Magnetics, Reno, NV (US)

(72) Inventors: John Othniel McDonald, Reno, NV (US); ERSED AKCASU OSMAN, CARDIFF-BY-THE-SEA, CA (US)

(21) Appl. No.: 19/147,886

(22) PCT Filed: Jan. 12, 2024
(86) PCT No.: PCT/US24/11345

§ 371 Date: Jul. 14, 2025

Related U.S. Application Data
(60) Provisional application No. 63/438,743, filed on Jan. 12, 2023.

(51) Int. Cl. H05K 1/16; H01F 1/147; H01F 17/00; H05K 3/00

(52) U.S. Cl. CPC H05K 1/165; H01F 1/14708; H01F 17/0013; H05K 3/0047; H01F 2017/002; H05K 2201/086

(57) ABSTRACT

Presented herein is a method of producing an inductor or inductor pair through a substrate, for example, a substrate core or carrier. The inductors have at least one winding which connects through the substrate. The inductors suffer the loss performance from the winding piercing the substrate, but are thus allowed to be arraigned, during manufacturing and subsequent use, according to a common centroid approach. This produces nearly identical inductors well suitable for matching or pairing.

### BACKGROUND

The general field of the present invention relates to the field of magnetics and, more specifically, to the methods and apparatus of matching inductors.

Discrete Inductors are usually built individually or alternatively in large lots sizes, then singulated and sold individually. The process of testing and packaging individually results in the discrete part upon placement on a printed circuit board having performance characteristics that cannot be predicted to be better than the overall process tolerance, which in many cases is as high as +/−10% to +−/20%.

In most cases, Discrete Inductors, for example, in a DC/DC converter circuit, are usually placed next to an Integrated Circuit (IC). As such, the IC manufacturer has no additional knowledge of what the performance and tolerance of the external inductor beyond the min/max specification provided by the inductor manufacturer. Therefore, the IC designer, in most cases, will need to design the IC to be tolerant of the worst-case tolerances at +/−10% to +/−20%.

To make matters worse, numerous modern power converter architectures that have been introduced to mitigate the significant thermal issues of high-performance processors, improve power efficiency in chargers, and reduce the total power conversion solution size use multi-phase/channel circuits which include multiple uncoupled inductors, one or more coupled inductors, transformers. These types of multi-phase/channel designs must consider the performance mismatch between the magnetic components to ensure the current flow through all the channels is balanced. Balancing current flow is required for a number of reasons, including ensuring an even distribution of thermal dissipation, improving component reliability, and reducing the solution size. The alternative to balancing the current flow is to design each channel to the worst-case tolerance specifications, resulting in a solution size that could be 2× to 10× larger with a comparable manufacturing cost increase.

Further, all power circuits with a magnetic component such as an inductor, transformer, or any of their variations in single or multiple form must deal with tolerance and mismatch issues. These power circuits are found in discrete DC/DC converters, DC/DC modules with integrated magnetics, and power management integrated circuits (PMIC) incorporating multi-phase buck, boost, or buck-boost converter ICs.

Often, the magnetic component is the largest component in a power conversion circuit. So, to save size, many designers desire to cut the inductor size, but the smaller the inductors get, the harder it is to match or couple them without generating high electronic noise and losing power conversion efficiency and stability. If paired (matched or coupled) inductors vary significantly in their inductance (L), resistance (R), and capacitance (C) electrical characteristics, then ensuring a balanced current is difficult. This is an issue when applications that are designed for two inductors of the same value, for example, coupled inductor DC/DC or LLC converters, must ensure that the current through each inductor is close to identical.

The negative effects from mismatching can arise due to manufacturing tolerances that prevent inductors in a pair from being physically identical. This physical mismatching has a bigger impact as the inductors get smaller and serves as a practical limit for how small the paired inductors can get in matched or coupled systems.

Unfortunately, current techniques of matching or coupling inductors are time-intensive or introduce design challenges by requiring mismatch compensation. For example, a matched inductor occurs and is useful when the inductors are on matched circuits or, in other words, their inductance, resistance, and capacitance are closely matched. There are at least two processes currently used to match inductors: “match screening” and “process matching.” Match screening involves screening inductors for similar performance and accepting low yield and some performance differences. Process matching involves building the inductors in close proximity using the same process steps at the same time such that their LRC values are as identical as possible at high yield.

However, both match screening and process matching so far do not produce identical inductor pairs. Screening for near identical inductors to pair is time-consuming and compounds error and tolerances from both the screening process and the manufacturing process. Match processing is subject to the issues of manufacturing tolerances discussed above. Both processes require designers and engineers to accept lowered pair performance as a limit or introduce complicated compensation schemes for the mismatched but paired inductors.

To eliminate or reduce manufacturing tolerances, or the effects of manufacturing tolerances, would enable smaller matched or coupled inductors to be generated by relying on screening methods.

However, there have been many efforts to create magnetic cored inductors in both PCBs as well as semiconductor packages over the years, but almost all efforts have economically failed due to the high manufacturing tolerances not allowing adequate performance compared to discrete solutions.

### BRIEF SUMMARY OF THE PRESENT INVENTION

By placing an inductor winding in a novel way that lowers the performance of an individual inductor, new layouts are introduced that significantly reduce mismatch in matched or coupled inductors while, in general, reducing the area requirements for integrated inductors. This allows for matched and coupled inductors to be used in smaller, more sensitive circuits.

Therefore, presented herein is a method of producing a matched inductor comprising taking a substrate; typically, a substrate core will be used, forming at least two through vias from a first surface of the substrate to a second surface of the substrate, which is the opposite surface of the first surface of the substrate; plating an inductor coil through the length of the vias to enable electrical connection through the through vias; and plating a first inductor on the first surface of the substrate and plating a second identical inductor on the second surface of the substrate so that the first inductor and the second inductor are electrically connected by the inductor coils traversing the through vias.

This forms a single inductor, also presented herein, which has a portion of coils on one side of a substrate and another portion of coils on the other side of a substrate (typically, in practice, the opposite side of the substrate). This inductor can take half of the space as an inductor plated on a signal layer. This inductor layout is unlocked by the placing of coil windings through the substrate itself, which reduces the performance of the inductor as a factor of how many coils pierce the substrate. It is worth calling attention to the fact that inductor windings pierce the substrate. In one exemplary embodiment the substrate is a printed circuit board for example. Other examples of substrates include but are not limited to Ajinomoto Build-Film or printed circuit board cores, and more examples of substrates are discussed later in this application.

This piercing of the substrate by inductor windings can be used to connect two inductors together as well. Therefore, also presented herein is a method of producing inductors comprising: taking a substrate; forming at least one through via from a first surface of the substrate to a second surface of the substrate which is the opposite surface of the first surface of the substrate; plating an inductor coil through the length of the vias to enable electrical connection through the through vias; and plating a first portion of an inductor on the first surface of the substrate and plating a second portion of the inductor on the second surface of the substrate so that the first portion of the inductor and the second portion of the inductor are electrically connected by the inductor coils traversing the through vias.

It should be noted that the methods of connecting inductors in this manner can be used to connect inductors which themselves are built with at least one first portion and at least one second portion of coils separated by the substrate. Many varieties of inductors may be plated and connected in this way. Further, more than one inductor may be connected, matched, or coupled in this manner so that inductor pairs may include more than two inductors.

In particular embodiments of the substrate may be a printed circuit board core or even a magnetic core. Thus the inductors may all have a core, that core may be for example nickel-iron. The inductors can be built out of many materials including copper, or hybrid materials. The inductors can also be integrated into systems as matched or coupled inductors or otherwise paired.

It is useful to layout the paired inductors according to a “common centroid” approach. This common centroid approach helps ensure that identical inductors are formed and that paired inductors respond the same to environmental stresses, such as, but not limited to, heat. For example three inductors can be arranged as if around a circle at 120 degree intervals, while four may be arranged at 90 degree intervals and so forth.

### DETAILED DESCRIPTION

In regard to matching or coupled inductors, it was noted by the inventor that to perfectly match inductors, the inductors did not be perfectly performing inductors. Instead, the inductors needed to be identical inductors. These identical inductors would have identical performance issues, and the design margin in compensation schemes would become extremely simplified. For example, a 10% compensation for both inductors in a pair as opposed to 10% for one inductor and 20% for the other inductor. The compensation schemes could then be used to counter the negative effects of reducing the inductor's performance. This ease in compensation allows for room to manipulate the inductor performance.

It is in essence, the “breaking” of the inductor that would allow for perfectly matching inductors. Here, the inductors have at least one winding that will be plated through the substrate or core. This reduces the performance of the inductor; in fact, plating too many windings through the substrate can render the inductor unusable. But this technique suddenly opens up the inductor to be plated on both sides of the substrate and even opens up plating multiple inductors as connected through the substrate. In turn, this opened up the ability to utilize a common centroid approach to inductor plating layout, not just in the final component design but also in the manufacturing process of the inductors.

The common centroid approach allows for inductors that are nearly identical to be formed. This is not an option for inductors plated on the same surface of a substrate. Let's take a look at what the common centroid approach allows.

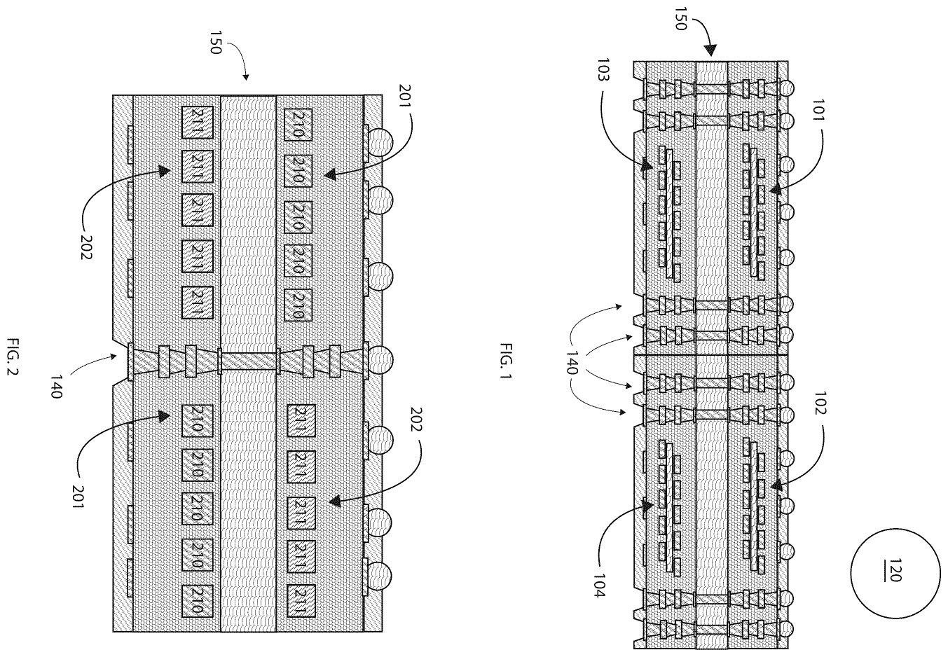

FIG. 1 shows four inductors placed according to a common centroid approach. Inductor 101 is coupled with inductor 104 and inductor 102 is coupled with inductor 103. Each inductor is coupled across substrate 150 through vias 140. There is a heat source 120 placed up and off to the side of the inductors. This situation can occur both when the inductors are in a system out in the world and during the manufacturing phase if the inductors are plated in the same electroplating bath.

In the electroplating bath the heat reaching inductors 101 and 192 from heat source 120 would be different and this difference would result in different plating rates for inductors 101 and 102 resulting in a physical mismatch. This holds true for inductors 101 and 102 here. But inductors 103 and 104 are coupled to inductors 102 and 103 respectively. The sum of the heat over each coupled pair is the same, resulting in inductor pairs that have the same rate of plating as each other. Outside of the plating bath, each inductor would, for example, have the same average thermal expansion due to heat source 120 and thus remain proportionally identical.

The physically identical inductor pairs will accept identical compensation making the design process much easier for engineers. Further this process can be used on single inductors to create inductors where the coils are matched as well. This can take inductor layouts to new levels and worlds not previously accessible.

FIG. 2 shows a cross-section of two inductors paired together. There is inductor 201 and inductor 202. Inductor 201 and inductor 202 form an inductor pair and have coils 210 for inductor 201 and 211 for inductor 202 on both sides of substrate 150. It will be noticed that the coils of inductor 201 and inductor 202 are offset. This offset expands the common centroid principals as each set of inductor coils is built around the common point 160 and then connected with the same center 160.

These inductor pairs can be matched or coupled inductors and are suitable for inductor coupling, transformers, or multi-phase designs. By building inductors on both sides of a substrate they can easily integrate into semiconductor packaging or on printed circuit boards. This is great because it has become commonplace in the semiconductor industry to build semiconductor packages by building them up layer by layer around the upper surface of a flat panel substrate core. Allowing inductors to be plated on the upper and lower surfaces of the same core, allows for easily integrated compensated matched inductor circuits. This eases the design effort, improves power efficiency, and lowers system cost.

Because the common centroid approach is now unlocked, and expandable, these systems can integrate multiple pairs of inductors. This is useful as a widespread application of matching inductors is in power management integrated circuits (IC) such as in multi-phase buck, boost, or buck-boost converter ICs. Here there are phases requiring inductor pairs, the minimum number of phases is 2, and it is common to have an even number of phases such as 2, 4, 6, . . . . ECT. to improve the ripple and noise. Also, as another example, RF differential amplifiers, typically named LNA (Low Noise Amplifiers), have inductor pairs in each branch of 2 LC circuits (tank circuits). In general, the inductors presented herein are suitable for inductor coupling, transformers, or multi-phase designs.

There are two general categories of layout created by allowing the inductor windings to pierce the substrate. The first category is for individual inductors that are split through the substrate and the second is for multiple inductors separated by the substrate but still paired by a winding piercing that substrate. Each category has two cases and thus two cases involve the splitting of single inductors while the remaining two involve the connecting of two or more inductors through substrate. However, it is worth noting that these general categories, and even the cases, can be combined in many ways. It also is worth noting that these inductors may pierce part of the substrate, for example a substrate core, and then serve a substrate themselves later on in manufacturing or design, for example in the design of a printed circuit board.

The first case we will discuss is the splitting of a single inductor across a substrate. For example, a set of inductor coils is formed on the upper surface of a substrate core and another set of inductor coils are formed on the opposite of the substrate. We can call this case 1.

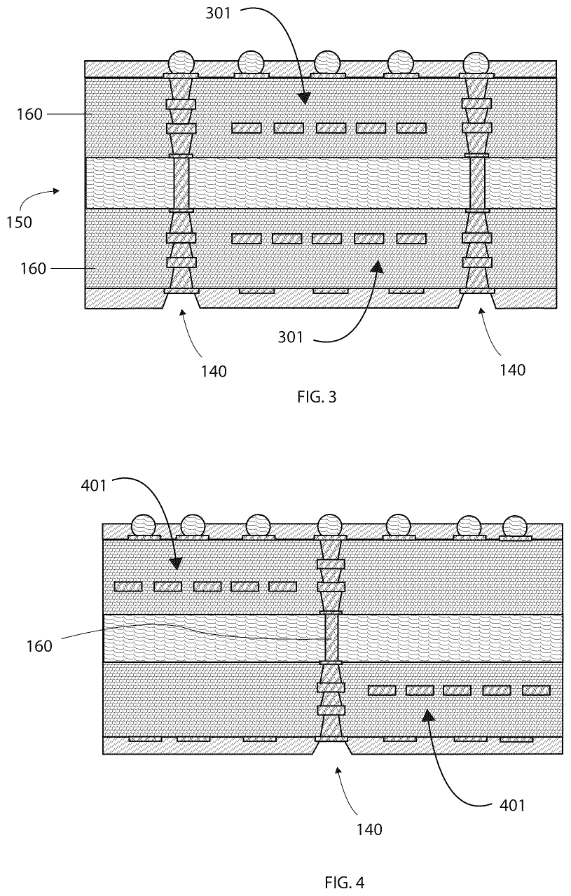

FIG. 3 shows an exemplary example of a case 1 layout. Here there are inductor coils 301 on both sides of the substrate 150 and these coils 301 belong to the same inductor. Two windings 140 pierce the substrate 150. In this example the coils 301 are held in build-up film 160. From FIG. 1 you can see that here the inductor simply pierces the substrate with at least one winding to connect the coils. It has been found that three windings through the substrate may be the optimal number of windings.

The second case takes case 1 and arranges it according to common centroid principles meaning that the inductor will be formed so that it can be integrated into common centroid designs and maintain that common centroid design.

FIG. 4 shows an exemplary case 2 layout. Here inductor coils 401 on both sides of substrate 150 belong to the same inductor; however, the coils 401 are offset so that they rotate around a common center 160 (the center is only marked and is not physically differentiated). A full offset where coils 401 do not overlap will allow another set of coils to be placed according to the case design in the empty space to form the multiple inductor case as shown in FIG. 2.

The second category of layout involves multiple inductors which are not halved. This allows for creating multiple identical inductors.

FIG. 5 shows a case 3 inductor layout. Here Inductors 501 and 502 are separated by a substrate 150 but are still connected by windings 140 through the substrate 150. These inductors may have their own core 510. Since each of the inductors have their own layer for a given horizontal area, except for any through-substrate winding used to pair the inductors the total inductor area for the paired inductors is cut down to half for even numbers of inductors and just less than half for odd numbers of inductors when compared to single-level inductor layouts.

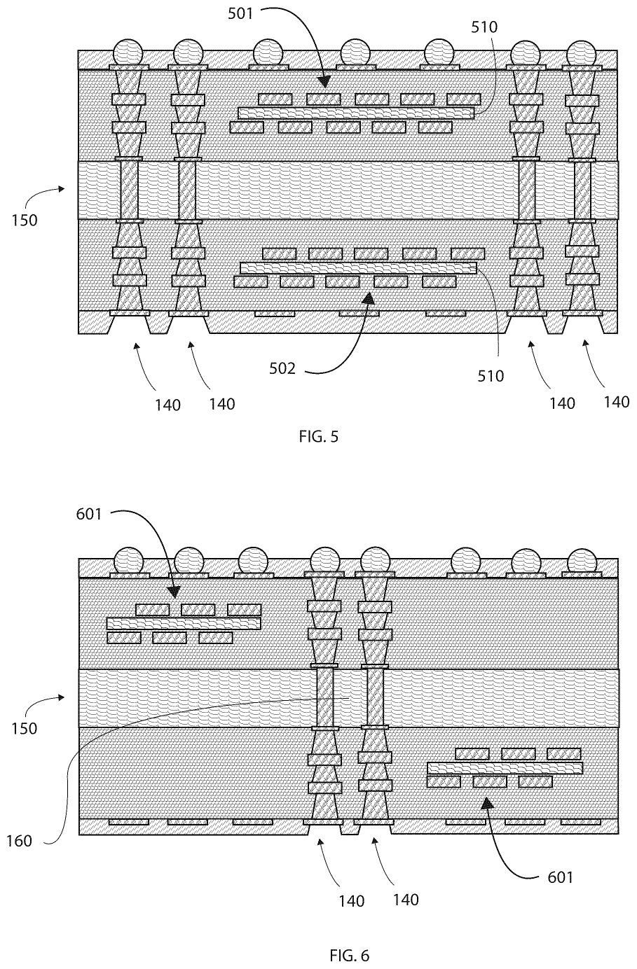

FIG. 6 shows a case 4 inductor layout. Here inductors 601 and 602 are separated by a substrate 150 and are offset so that they rotate around a common center 160 (as in FIG. 4, the center is only marked and is not physically differentiated). Here, as shown, the inductors are wholly offset, but they are still paired. This will allow for another set of case 3 inductors to be placed according to a common centroid approach and thus provide for two inductor pairs arranged according to the common centroid approach.

The benefits of each case will be discussed further below, but it is first important to note that there is no reason for not having an odd number of inductors and each case can accommodate such a number of inductors or inductor pairs while providing area savings.

Table 1, which follows, shows the area savings for a given number of matched inductors, where S1 is the area of a single layer inductor (not of this invention) where n=1, 2, 3, . . . ect.

| | Horizontal (H) Inductor | | |
|---|---|---|---|
| | area if all built on a | H Inductor | H Inductor |
| # of | single layer on a single | area if | area if |
| Inductors | core side surface | case 1 | case 3 |
| 1 | S1 | 0.5*S1 | S1 |
| 2 | 2*S1 | S1 | S1 |
| 3 | 3*S1 | 1.5*S1 | 2*S1 |
| 4 | 4*S1 | 2*S1 | 2*S1 |
| 2n (Even number) | 2n*S1 | n*S1 | n*S1 |
| 2n + 1 (Odd | (2n + 1)*S1 | (2n + 1)*S1/2 | (n + 1)*S1 |
| number) | | | |

From this table it can be seen that both odd and even numbers of inductors will take less space in case 1 and case 3 examples than if the inductors are built on a single layer. In fact, by occupying both the upper and lower sides of a carrier, they fit into a smaller two-dimensional area. Thus, comparatively, in a circuit, the total matched H inductor area may be halved for a given number of inductors in any application!

The issue is more complicated in case 2 and case 3 inductors. In general, a case 2 inductor will take up more horizontal space than an inductor built on a single layer; while a case 3 inductor pair will take up the same horizontal space as two inductors built on the same layer. However, the area will not expand for case 1 when another inductor is placed as shown in FIG. 4 and thus two case 2 inductors can be placed in the same horizontal space as two inductors built on the same level. With regard to case 2 the horizontal area will not expand with the addition of another inductor pair into the system as shown in FIG. 6, and as a result, a double inductor pair of case 4 will take up half the horizontal space as the equivalent four inductors placed on the same layer.

However, even in instances where case 2 and case 4 do not conserve horizontal space they still allow for the benefits that come from identically formed inductors. This is true in all four cases, as the inductors are copies of each other and connected. One the compensation mismatch issues are greatly reduced. So, in a matched inductor pair, for example, both inductors will require the same compensation as opposed to one inductor requiring a 5% compensation and the other requiring a 10% compensation. Further inefficiencies related to thermal expansion affecting one inductor pair more than other or one inductor coil more than the other will be reduced.

We have now described the fundamentals of case 1-4 layouts and we can answer how they are made and then discuss the benefits of each layout in more detail.

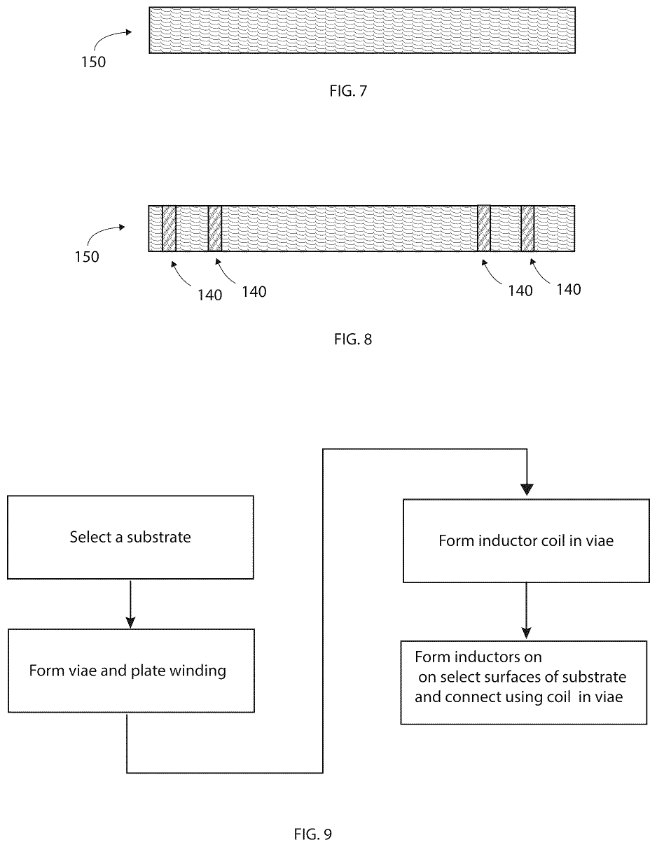

For all cases as presented herein the inductors are formed on a substrate. Thus FIG. 7 shows the initial start condition of the coupled inductor in all cases—a substrate 150. In at least one exemplary embodiment, the substrate is what is commonly known in the industry as a substrate core. But, the substrate may be selected on a variety of factors for example, for enhanced mechanical, thermal, or electrical or cost; and from a variety of cores types, including but not limited to, epoxy, fiberglass, Ajinomoto Build-Up film, silicon, polymers, various films, or any core or core similar to what is in use in the printed circuit board, semiconductor packaging, semiconductor wafer, or the lamination industry. In at least one exemplary embodiment, the inductors are built on a carrier. The carrier may be but is not limited to a material such as FR-4 or other epoxy glass. Any carrier common in the industry is suitable to serve as a carrier here. It will be appreciated that in some exemplary embodiments the substrate may be a multi-layer substrate.

FIG. 8 shows the carrier with vias 140 formed and plated. Vias 140 are formed, for example, drilled, to allow the inductors to connect and pair through the substrate. Once formed, the vias are plated with a material that allows the transfer of current through the vias. This may be an inductor winding as this allows for the simple coupling of magnetic flux through the substrate-which gives the inductors or inductor coils on both sides of the carrier the property of a matched or coupled inductor. (Coupled inductors are coupled by the transfer of magnetic flux from one pair of windings to another.)

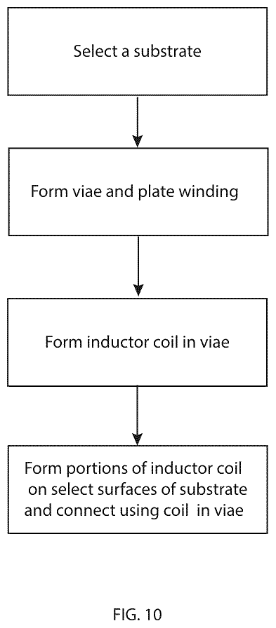

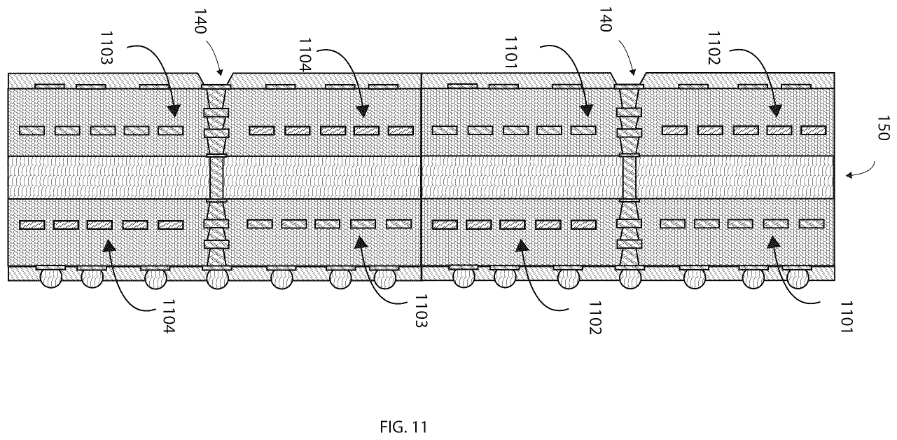

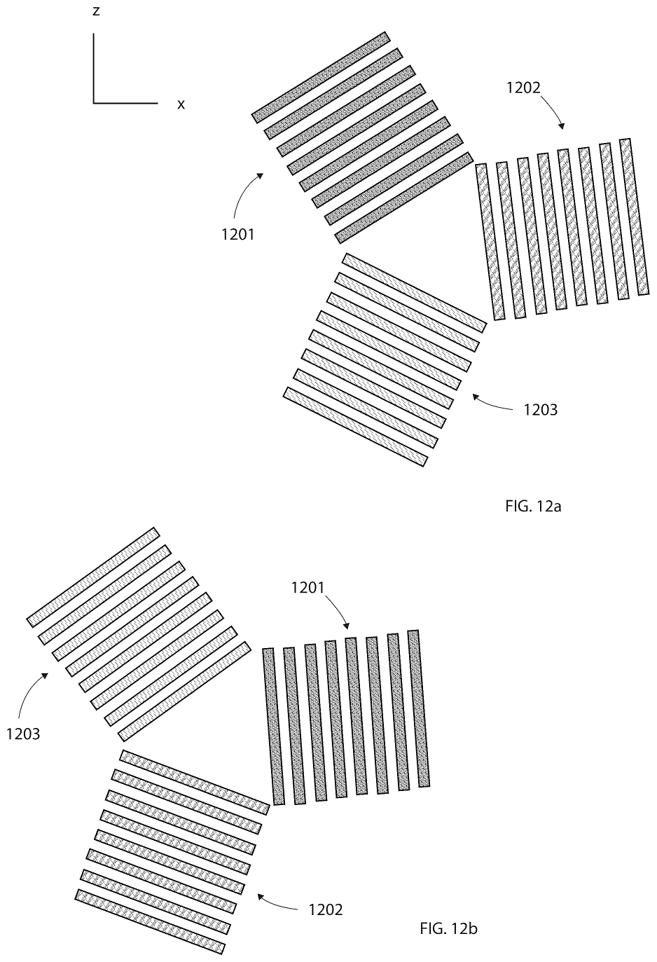

It is here that the categories diverge in the plating methodology. As shown in FIG. 9, plating cases 1 and 2 have the steps of selecting a substrate, forming and plating coils in the vias, and then plating a portion of inductor coils on one side of the substrate and another portion of the inductor coils on another surface of the substrate. Whereas, as shown in FIG. 10, it is not portions of an individual inductor plated on each side, but in fact individual inductors.

In case 1 and 2. The inductor coil portions are plated onto the substrate. An example of a result for case 1 is shown in FIG. 3. Here a single inductor 301 has been formed with half of the inductor on one side of the substrate 150 and the remaining half of the inductor on the opposite side of the substrate. There is at least one via 140 that has been plated with an inductor winding, but the via need not be plated in the location as shown.

Notice that in the FIG. 3 case 1 example, although the coils can be plated with any portion except zero on top and any portion except zero on the bottom, half of the inductor coils have been plated on top and half of the inductor coils have been plated on the bottom of the substrate. Forming the inductor in this half and half arraignment minimizes the horizontal space.

FIG. 4 as discussed above shows a case 2 example where the inductor 1 is halved across substrate 150. A defining feature of case 2 is that the inductor coils have also been offset. This offset will allow for the common centroid principles to be applied even as the system includes or pairs multiple inductors. It will be appreciated that individual case 1 and case 2 inductors can be paired with other inductors.

FIG. 2 as also discussed above shows two case 2 inductors, inductor 201 and inductor 202, that have been paired together in a common centroid approach. Inductors 201 and 202 are arranged so that the 210 coils (i.e. a portion of inductor 201) is directly across the substrate 150 of the 211 coils (i.e. a portion of inductor 202). This centers the inductor around point 160. The inductors can be matched or coupled through at least one winding traveling through at least one via.

However, this approach is not limited to two inductors, as FIG. 11 shows four inductors: inductor 1101, inductor 1102, inductor 1103, and inductor 1104. Although we have noted above that case 2 is not the optimal case for space saving, we can use this expansion into multiple inductors to see that case 2 can unlock unique inductor layouts.

To better understand this, we leave the cross-sectional view for a top-down view. For reference FIG. 12a shows a bottom-up view of a layer having three inductor coil portions already arranged according to common centroid principles. This is the lower layer of a case 2 instance. FIG. 12b shows a top-down view of the same case 2 instance, but now revealing the inductor coil portions on top. Here we can see that the coils belong to one of three inductors, inductor 1201, inductor 1202, and inductor 1203. The inductors are stacked so that the upper portion of inductor 1201 sits on the lower portion of inductor 1203, the upper portion of inductor 1202 sits on the lower portion of inductor 1201, and the upper portion of inductor sits on inductor 1203. Essentially the top and bottom portions of each inductor are offset by 1.

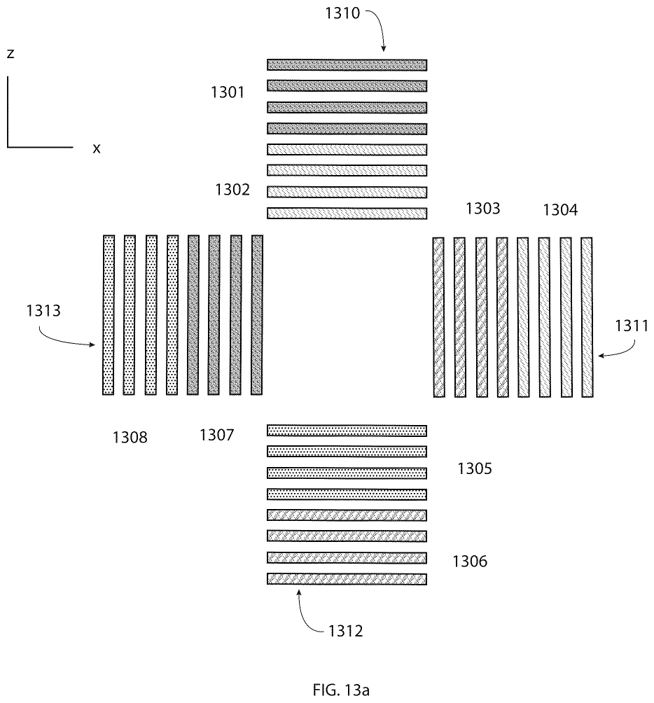

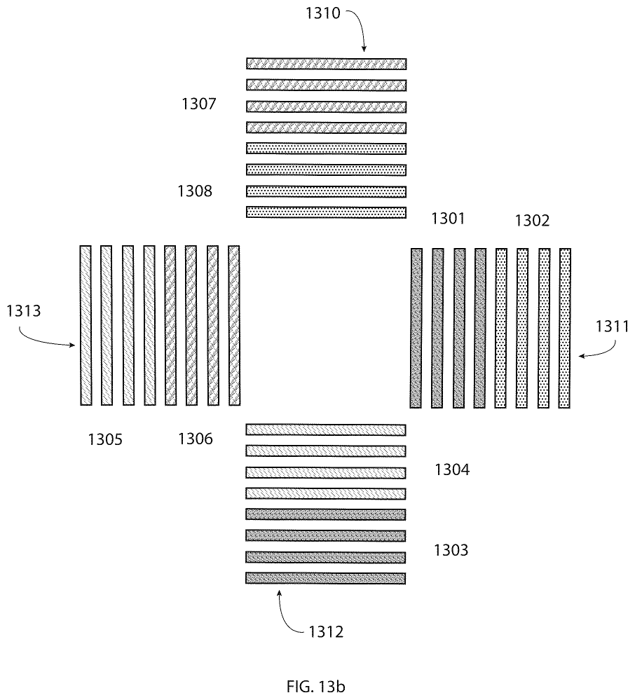

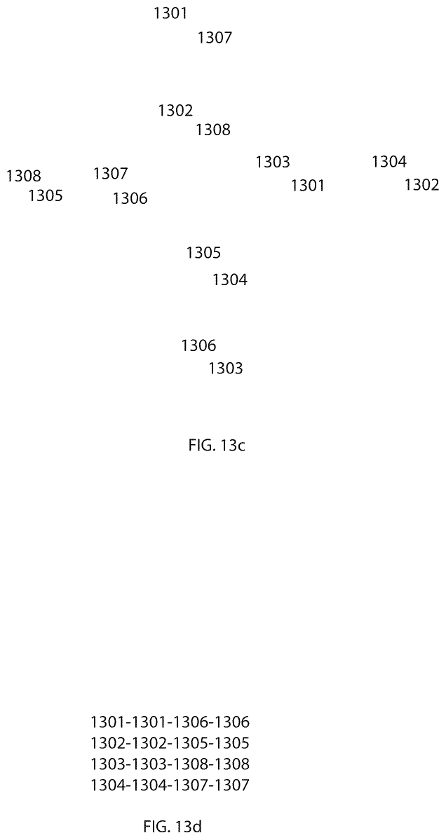

But it can get more complex. The result is the following configuration shown in FIGS. 13a and 13b. FIG. 13a depicts a top-down view showing four inductor coil portions arraigned in a ninety-degree plus configuration. Inductor 1301, inductor 1302, share prong 1310 of the plus. Inductor 1303 and inductor 1304 share prong 1311 of the plus. Inductor 1305 and 1306 share prong 1312 of the plus. Inductor 1307 and inductor 1308 share prong 1313 of the plus.

FIG. 13b depicts a bottom-up view of the same case 2 instances. Here each inductor is offset from its original portion so that on the bottom layer inductor 1307, inductor 1308, share prong 1310 of the plus. Inductor 1301 and inductor 1302 share prong 1311 of the plus. Inductor 1304 and 1303 share prong 1312 of the plus. Inductor 1305 and inductor 1306 share prong 1312 of the plus. Here for example, inductor 1301 is paired with inductor 1306, inductor 1302 is paired with inductor 1305, inductor 1303 is paired with inductor 1308, and inductor 1304 is paired with inductor 1307. For clarity FIG. 13c depicts a symbolic interpretation of FIG. 13a and FIG. 13b. Here the numbers in the plus represent the order and location of the inductors. The sub number represents the lower inductor portions. FIG. 13d shows a chart of an example order of the inductor pairing, however, the order may vary.

This is an optimal configuration, and it will be appreciated that Case 2 unlocks the arraignment types of FIG. 12a-b and FIG. 13a-d. However, it is worth mentioning again that the windings of the inductors may be arranged so that any portion is on the upper surface and any remaining portion is on the lower surface. The portions need not be continuous but may alternate from the upper surface to the lower surface and back to the upper surface. To optimize the matched inductors, each inductor should be the same length, and the arrangement is guided by the common centroid approach. Therefore, there is a wide range of potential layouts within each of the cases.

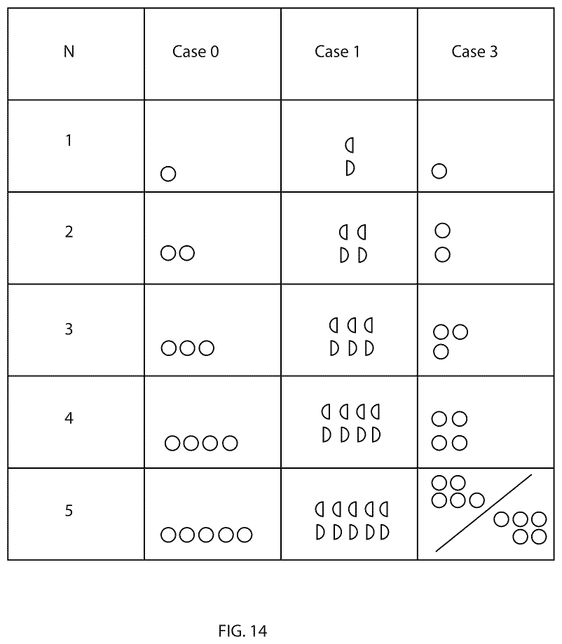

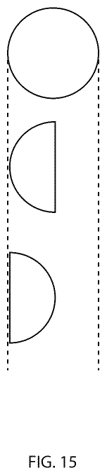

It will be appreciated that one result of splitting inductors is a significant reduction in substrate core area. FIG. 14 demonstrates Case 1 and Case 3 compared to Case 0, which is not part of the invention, but is the case when inductors are plated on only one side of the substrate core.

In FIG. 14, N is the number of inductors, and the substrate core area in question is generated by the length and width of the substrate core. Thus it can be seen, for example, in N3, case 0 requires a core area that can hold three inductors side by side, whereas case 4 requires only an area for two inductors side by side, and case 1 requires only an area for one and a half inductors side by side.

Case 1 can provide the smallest fit of a core as it can fit two cores in the space of one core. This is demonstrated by FIG. 15 where it can be seen that separating each core in half and putting one portion of the core on the top surface and the other half of the core on the bottom surface may result in a substrate core area requirement that is only half of a case 0 core. This occurs because the case 1 core area is only half of a case 0 core area.

Now it is worth discussing case 3 and case 4 layouts. As previously noted, FIG. 5 shows an inductor arraignment with individual inductors plated on both sides of the carrier. It is worth adding that the arrangement of the inductors is identical, and the inductor windings of each are connected by vias to the inductor windings of the other. The inductor windings through the vias are a small portion of the total windings and thus only slightly, and not significantly, affect individual inductor performance. In a preferred embodiment, the number of windings through the vias is less than three windings.

It is also worth restating that, although the windings through the core slightly reduce the inductor performance, they connect the inductors together through the carrier—opening up new placement schemes for inductors and improving the ability of each inductor to work together by removing compensation mismatch issues.

As shown in FIG. 5 each of the inductors, inductor 501 and inductor 502 may have a core 510. The inductor cores may be a nickel-iron material, a combustion chemical vapor deposition (SiO₂) insulation layer, or any core material suitable for use as a core in the microelectronics industry. As presented in FIG. 5, the inductor of case 2 is ready for integration into an electrical system, such as a system-in-package. These inductors take up significantly less horizontal substrate space than single-layer plated inductors.

Although directly connected by windings, case 3 and case 4 inductors can be thought of as matched or coupled inductors. This provides a distinction between two inductors and a single larger inductor, as here, you can use one inductor for one phase of a DC-to-DC converter and the other inductor for a second phase of the DC-to-DC converter.

A significant benefit of these inductors, in all cases, is their ability to resist damage from thermal expansion. As these inductors are of the same materials, in the same shape, and on the same carrier, they are matched in terms of thermal expansion and, therefore, have matched responses to the expansion.

The capability to plate an inductor on both sides of the carrier allows for unique inductor arraignments with multiple inductors and inductor pairs. These arrangements can optimize matching inductors to withstand environmental conditions without altering the compensation scheme, even across inductors for multiple-phase converters, such as two or three-phase converters.

As noted above, FIG. 1 shows an inductor configuration for a two-phase converter. Here, inductor 101 is paired with and connected to inductor 103, while inductor 102 is paired with and connected to inductor 104. A winding for each inductor goes through one of the vias to connect the inductor with its counterpart. This is an example of a case 4 inductor layout with two case 4 inductor pairs.

This is a prime example to demonstrate the ability of the common centroid approach to reduce compensation mismatch errors during manufacturing. As an example, FIG. 1 shows a heat source 120 nearer to inductor 102 than the other inductors. This heat source may be present during plating in a plating bath during the manufacturing process and cause the plating rates of material to differ slightly throughout the area of the bath. Given the position of heat source 120 and the matching arraignment of the inductors: inductor 103 will have the lowest temperature, and inductor 102 will have the highest temperature during plating. But the inductor pairs of 101 and 103 as well as 102 and 104 will have the same average temperature as each other because the average distance of each pair is the same.

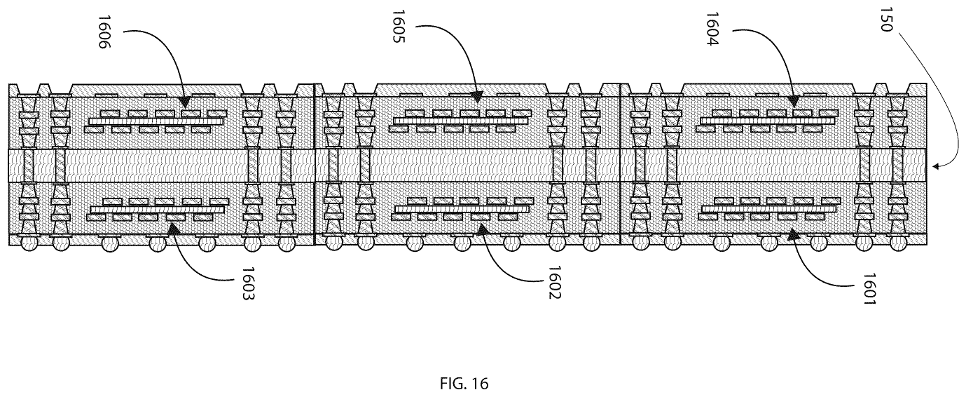

The average effect is strongest when offset inductors are paired through the carrier. However, inductors can be paired with the inductor directly opposite them or with the offset inductor, depending on the total number of inductors. Therefore, with the inductors shown in FIG. 16, each inductor can be paired with the inductor directly opposite it, as 1601, 1604; 1602, 1605; and 1603, 1606. These pairs still require less carrier length than the same number of inductors on the same side of the carrier and are partially arranged according to a common centroid principle while keeping the inductor length the same between pairs. However, a stronger common centroid-based approach may be a 1601,1605, 1603 and a 1604, 1602, 1606 linkage.

When inductors are arranged according to a pure common centroid approach, the average temperature experienced by the inductor pairs is the same. This is true even if the heat source is not offset. However, specific inductors within a pair will expand at different rates; what is important is that the average across pairs will match.

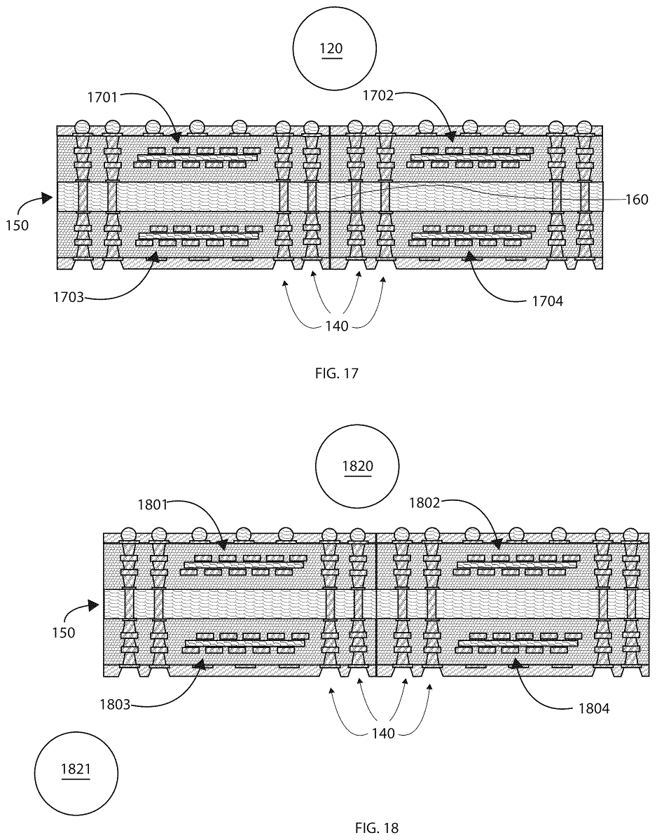

FIG. 17 shows a heat source 120 centered above and between inductors 1701 and 1702. Here inductors 1701 and 1702 will have the same temperature, while inductors 1703 and 1704 have a matching temperature that differs from the temperature of inductors 1701 and 1702. Due to the 1701, 1703, and 1702, 1704 pairing arraignment, the inductor pairs will present the same average temperature. This also means that thermal expansion will match across inductor pairs. To keep the temperature the same when the heat source is offset, however, pair across the common centroid point 160.

In this case, there is more than a single element in a system that affects the performance of the inductors; a common centroid approach still works to minimize compensation issues. FIG. 18 shows a system affecting element 1820 above the inductors (inductor 1801, inductor 1802, inductor 1803, inductor 1804) and a system affecting element 1821 below the same inductors, with system affecting element 1820 having a greater effect on the inductors than system affecting element 1821. Although each system-affecting element differs in its ability to affect the system, the inductors are still averaged between the elements and thus matched without added difficulty.

Although in general the environmental stressor is shown as a heat source 120 in the figures, the inductors will most likely be subjected to many system-affecting elements at once from voltages to pH to temperature. For instance, while plating, both the temperature of the bath and the voltage of the bath will affect the deposition rates of the inductor material. In post-manufacturing, an inductor may be subject to several heating sources and pressures.

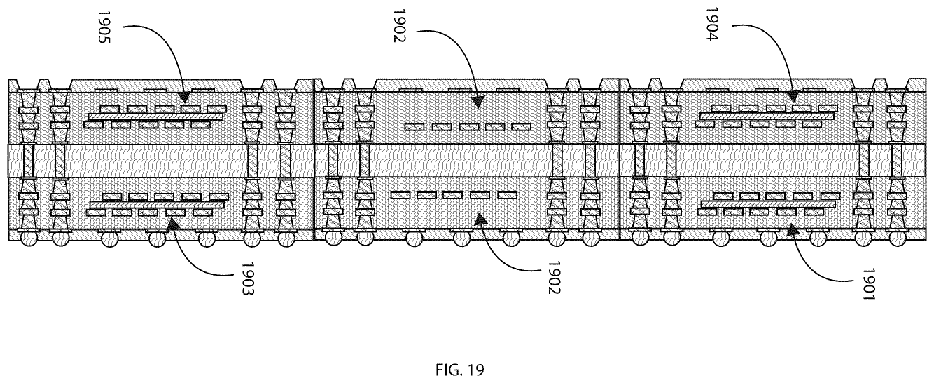

Although it is often best to utilize the common centroid approach to its fullest there may be instances where it may be best to invoke but not optimize the common centroid approach. All cases of inductors can fit together to produce a wide variety of arrangements. Not all embodiments need to be fully optimized or perfectly matched, but they may still be manufactured regardless. For example, a substrate may be plated with a combination of the cases and categories. For example, a case 1 middle inductor (1901) with two paired Case 3 Inductors (1901,1904) and (1903,1902) as shown in FIG. 19.

The drawings and figures show multiple embodiments and are intended to be descriptive of particular embodiments but not limited to the scope, number, or style of the embodiments of the invention. The invention may incorporate a myriad of styles and particular embodiments. All figures are prototypes and rough drawings: the final products may be more refined by one skill in the art. Nothing should be construed as critical or essential unless explicitly described as such. Also, the articles “a” and “an” may be understood as “one or more.” Where only one item is intended, the term “one” or other similar language is used. Also, the terms “has,” “have,” “having,” or the like are intended to be open-ended terms. The inductor form may vary from the inductors shown in the drawings. An inductor built on an upper or lower surface of the core may also be built in a layer or layers above the upper surface or below the lower surface of a core.

1. A method of producing a matched inductor comprising:
taking a substrate;
forming at least two through vias from a first surface of the substrate to a second surface of the substrate, which is the opposite surface of the first surface of the substrate;
plating an inductor coil through the length of the vias to enable electrical connection through the through vias; and
plating a first inductor on the first surface of the substrate and plating a second identical inductor on the second surface of the substrate so that the first inductor and the second inductor are electrically connected by the inductor coils traversing the through vias.

2. The method of claim 1, wherein the substrate is printed circuit board.

3. The method of claim 1, wherein the substrate is Ajinomoto Build-Up Film.

4. The method of claim 1, wherein at least one of the upper or lower inductors has its own magnetic core.

5. The method of claim 1, wherein at least one of the inductors formed is a hybrid material.

6. The method of claim 1, further comprising integrating the plated inductors into a system as coupled inductors.

7. The method of claim 1, further comprising integrating the plated inductors into a system as matched inductors.

8. The method of claim 1, wherein the number of the inductor windings through the carrier is less than three windings.

9. The method of claim 1, further comprising repeating at least once the steps of drilling at least two vias, plating an inductor coil through the vias, and plating a first and second inductor matched to form at least one additional pair of inductors on the same substrate.

10. The method of claim 9, wherein each inductor pair is comprised of offset inductors.

11. The method of claim 10, further comprising arranging the inductors according to a common centroid approach.

12. An inductor arraignment comprising:
a substrate with at least one through vias from a first surface of the carrier to a second surface of the carrier which is the opposite surface of the first surface of the substrate;
at least one upper inductor on the first surface of the substrate;
at least one lower inductor on the second surface of the substrate; and
At least one of the upper inductors is operably connected to the lower inductors by at least one coil of the upper inductor traveling through at least one via forming an inductor pair.

13. The matched inductors of claim 12, wherein at least one of the upper or lower inductors has its own magnetic core.

14. The matched inductors of claim 12, wherein the magnetic core is a nickel-iron core.

15. The matched inductors of claim 12, wherein the magnetic core is a hybrid SiO2 layered core.

16. The matched inductors of claim 12, wherein the number of the inductor windings through the carrier is less than three windings.

17. The matched inductors of claim 12, further comprising at least one additional inductor and each of the additional inductors arranged on the first surface of the substrate or the second surface of the substrate.

18. The matched inductors of claim 15, wherein each inductor pair is comprised of offset inductors.

19. An inductor arraignment comprising:
a substrate with at least one through via from a first surface of the substrate to a second surface of the substrate which is the opposite surface of the first surface of the substrate;
a first portion of an inductor on the first surface of the substrate;
a second portion of the inductor on the second surface of the substrate; and
the first inductor portion is connected to the second inductor portion by at least one coil of the inductor traveling through at least one of the vias.

20. The inductor arraignment of claim 19, wherein the substrate is a printed circuit board core material.

21. The inductor arraignment of claim 19, wherein the number of the inductor windings through the vias is less than three windings.

22. The inductor arraignment of claim 19, wherein the inductors are arranged according to a common centroid approach.

23. The inductor arraignment of claim 19, further comprising at least one additional inductor and each of the additional inductors arraigned with a first portion of the additional inductor on the first surface of the substrate; a second portion of the additional inductor on the second surface of the substrate; and where first portion of the additional inductor is connected to the second portion of the additional inductor by at least one coil of the additional inductor traveling through at least one of the vias.

24. The inductor arrangement of claim 19, wherein each of the first portion and the second portions of the inductors are offset across the substrate.

25. The inductor arraignment of claim 19 wherein there are at least two inductors arraigned in a symmetrical arraignment.

26. A method of producing inductors comprising:
taking a substrate;
forming at least one through via from a first surface of the substrate to a second surface of the substrate which is the opposite surface of the first surface of the substrate;
plating an inductor coil through the length of the vias to enable electrical connection through the through vias; and
plating a first portion of an inductor on the first surface of the substrate and plating a second portion of the inductor on the second surface of the substrate so that the first portion of the inductor and the second portion of the inductor are electrically connected by the inductor coils traversing the through vias.

27. The method of claim 26, wherein the substrate is printed circuit board.

28. The method of claim 26, wherein the substrate is Ajinomoto Build-Up Film.

29. The method of claim 26, wherein at least one of the inductors formed is a hybrid material.

30. The method of claim 26, further comprising integrating the plated inductors into a system as coupled inductors.

31. The method of claim 26, further comprising integrating the plated inductors into a system as matched inductors.

32. The method of claim 26, wherein the number of the inductor windings through the substrate is less than three windings.

33. The method of claim 26, further comprising repeating at least once the steps of drilling at least two vias, plating an inductor coil through the vias, and then plating a first portion of at least one additional inductor on the first surface of the carrier and plating a second portion of the additional inductor on the second surface of the substrate so that the first portion of the inductor and the second portion of the inductor are electrically connected by the inductor coils traversing the through vias.

34. The method of claim 33, wherein each inductor pair is comprised of offset inductors.

35. The method of claim 33, further comprising arranging the inductors according to a common centroid approach.
